(19) United States
(12) Patent Application Publication
(10) Pub. No.: US 2025/0155477 A1
(43) Pub. Date: May 15, 2025

(54) PROCESS FOR CURRENT MEASUREMENT COMPRISING A DIGITAL RECOMBINATION OF A LOW-FREQUENCY CURRENT SIGNAL AND AT LEAST ONE HIGH FREQUENCY CURRENT SIGNAL

(71) Applicant: SAFRAN ELECTRICAL & POWER, Blagnac (FR)

(72) Inventors: Jean-Pierre BALBINOT, BLAGNAC (FR); Guillaume GUINDE, BLAGNAC (FR)

(73) Assignee: SAFRAN ELECTRICAL & POWER, Blagnac (FR)

(21) Appl. No.: 18/720,047

(22) PCT Filed: Dec. 9, 2022
(86) PCT No.: PCT/FR2022/052307

§ 371 Date: Jun. 14, 2024

(30) Foreign Application Priority Data
Dec. 14, 2021 (FR) 2113452

(51) Int. Cl. G01R 19/00; G01R 15/18

(52) U.S. Cl. CPC G01R 19/0092; G01R 15/181; G01R 19/0007

(57) ABSTRACT

A process for current measurement includes a recombination of a low frequency current signal ILF coming from a low frequency current sensor and at least one high-frequency current signal IHF+offset coming from a high-frequency sensor on a single current conductor. The process includes the steps of amplification, filtering, and summing of signals suited to eliminating a direct offset created during amplification of the HF signals.

### FIELD OF THE INVENTION

The present disclosure relates to measurements done with current sensors in particular with onboard current sensors in the field of avionics and provides in particular for a process for current measurement comprising a digital recombination of a low-frequency current signal coming from a low-frequency current sensor, and at least one high-frequency current signal coming from a high-frequency current sensor.

### DESCRIPTION OF RELATED ART

Measuring currents with current sensors by using analog electronic components is known. These components lead to problems with precision and temperature stability and require an offset voltage correction with a relatively long stabilization time. The offset voltage is measured by integrating the measured signal to determine the average voltage from it and it is necessary to have a long time-constant, several seconds, integrator. A consequence of this is the need to wait for an equivalent stabilization time before being able to get the result of the measurement; this is penalizing in particular in case of micro-breaks of the electronic supply to the sensor such as from starting up power devices or power switching on the electrical network of the aircraft.

### BRIEF SUMMARY OF THE INVENTION

In light of the prior art, the present application proposes a measurement device intended to overcome the accumulation of dispersions related to the analog components by implementing a digital system containing very few discrete components and substantially reducing the stabilization time for the correction of the offset voltage.

In this context, the present invention relates to a process for current measurement comprising a digital recombination of a low frequency current signal ILF coming from a low frequency current sensor and at least one high-frequency current signal IHF coming from a high-frequency sensor measured on a single electrical line, where a parasitic continuous offset is added to said high-frequency current, which comprises steps:
a.—digitally amplifying said high-frequency signal with an amplifier having gain G which produces an amplified high-frequency signal: G·IHF+G·offset;
b.—first filtering of said high-frequency signal by means of a digital low-pass filter with a cutoff frequency fc to get a filtered amplified high-frequency signal Ihf+G·offset:
c.—second filtering of said low-frequency current signal ILF with a digital low-pass filter provided with said cutoff frequency fc in order to get a filtered low-frequency signal: Ilf;
d.—first summing of the filtered amplified high-frequency signal Ihf+G·offset with the filtered low-frequency current Ilf and filtering of the sum of said signals at frequency fc resulting in a signal: Ilf+Ihf+G·offset;
e.—third filtering of said signal Ilf+Ihf+G·offset resulting in a signal Ilf+G·offset from which the Ihf component is deleted;
f.—multiplying the signal Ilf by two resulting in a signal: 2 Ilf;
g.—adding/subtracting signals: 2 Ilf+(Ihf+G·offset)−(If+G·offset).

According to this process, the signals LF and HF are returned to scale and added without introduction of a parasitic offset to the HF signal.

The characteristics disclosed in the following paragraphs correspond to embodiments which may be implemented independently of each other or in combination with each other:

Said steps may advantageously be preceded by a step of analog-to-digital conversion of said low-frequency current and a step of analog-to-digital conversion of said high-frequency current, where said conversion steps are done on a digitized low-frequency signal and a digitized high-frequency signal.

The cutoff frequency fc is advantageously the cutoff frequency of the signal Ilf which gives a measurement continuity between the low-frequency and the high-frequency.

The invention also relates to a device for implementing the process which comprises calculation means configured for implementing the steps of the process.

Said calculation means may comprise means for analog-to-digital conversion of the signals.

The device may further comprise a processor suited for processing the data digitized from measured currents.

The present disclosure also relates to an aircraft equipped with a measurement device such as defined above.

### BRIEF DESCRIPTION OF THE DRAWINGS

Other characteristics, details and advantages of the invention will appear upon reading the following detailed description of nonlimiting implementation examples, and the analysis of the attached drawings where:

FIG. 1 shows a Bode plot applicable in the context of the invention;

FIG. 2 shows a simplified schematic of a device from the prior art;

FIG. 3 shows a schematic of a device from the present disclosure;

FIG. 4 shows a schematic view of a cascade of devices from the present disclosure.

### DETAILED DESCRIPTION OF THE INVENTION

The following drawings and description contain elements which can serve not only to better understand the present invention, but also contribute to definition thereof, as applicable.

In the case of using nonintrusive current sensors on high-power current lines, for example, a measurement of low-frequency currents is possible using Néel effect current sensors. These sensors have a good linearity from direct current up to a few hundred hertz. In contrast, if higher frequency currents are to be measured on the same line, up to a megahertz for example, other sensor technologies are needed like Rogowski coil current sensors.

For measuring from direct current up to a megahertz, combining the two technologies is desirable and a problem of compatibility of the measurements appears for linearizing the results of the two measurements because the two sensors and measurement technologies using them do not have the same gain.

A goal of the present disclosure is to increase the detection bandwidth for single signal with for example a very low bandwidth sensor, for example a Neel effect sensor with a bandwidth of a few hundred hertz, and a higher bandwidth sensor up to a megahertz, for example.

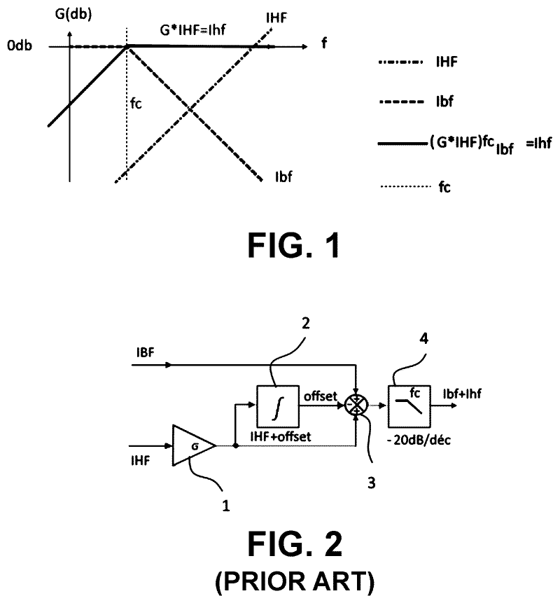

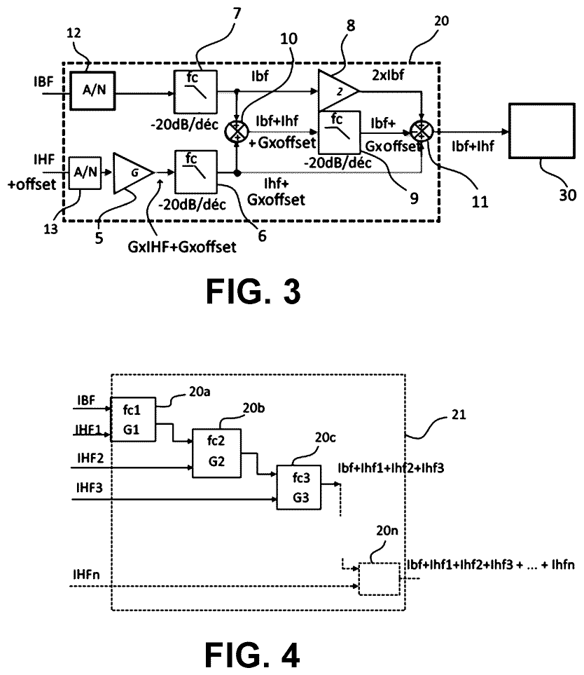

The principle of the combination of a current signal coming from a low-frequency sensor with a current signal coming from a high-frequency sensor according to the present disclosure is given in FIG. 1 which shows the principle used by a Bode plot of gain G vs. frequency f with the combination of an LF current and an HF current coming from a differentiator type sensor.

In FIG. 1, the current ilf may come from a Neel effect sensor and the current IHF may be a current coming from a sensor supplying the derivative of the current HF for example a Rogowski coil sensor. To return it to scale, this current IHF is amplified with a gain G and filtered with a low-pass filter with a cutoff frequency fc which is the cutoff frequency of the signal Ilf. (G·IHF)fc_{Ibf}=Ihf is thus obtained which is sufficient to add to Ibf to get a current whose bandpass is equivalent to that of the two original currents.

The problem caused by a device with two different recombined bandpass sensors is that the imperfection of the electronics used for measuring and amplifying the HF signal introduces an offset voltage added to the IHF which adds a direct or offset error signal to the measured HF current. It is therefore imperative to evaluate this offset in order to extract it from the calculated current.

A solution from the prior art such as described in FIG. 2 is to use an analog integrator whose output is the average value of the amplified current IHF and by using the following functions:

The signal IHF is amplified by the amplifier 1 with gain G which gives:

$$G \cdot IHF + G \cdot offset ; \qquad ( 1 )$$

The resulting signal is integrated in the integrator 2 which gives the signal:

$$G \cdot offset ; \qquad ( 2 )$$

An adder/subtracter 3 combines the signals ILF+G·IHF+G·offset−G·offset which gives the result:

$$ILF + G \cdot IHF ; \qquad ( 3 )$$

This signal is then filtered in a low pass filter 4 with cutoff frequency fc and slope −20 dB/decade according to the example getting Ilf+Ihf.

The problem comes up when measuring a current with a direct main component. Such a signal requires a very low frequency integrator which requires an even longer stabilization time when the frequency is low.

A solution according to the present disclosure is to do without an analog integrator by using, after digitization of the signals, a calculation process comprising the following options and by integrating it in a digital component 20 suited to implementing the signal processing:
The signal ILF is converted by an analog-to-digital converter 12 and then filtered by a digital low-pass filter function 7 at the cutoff frequency fc which gives:

Ilf (4),
The signal IHF is converted by an analog-to-digital converter 13 and then amplified by an amplification function 5 with gain G and filtered by a digital low-pass filter function 6 at the cutoff frequency fc which gives a current Ihf with an offset multiplied by the gain G:

$$Ihf + G \cdot offset , \qquad ( 5 )$$

The two previous results are added in an addition function 10 which gives:

$$Ilf + Ihf + G \cdot offset , \qquad ( 6 )$$

This result is filtered by a digital low-pass filter function 9 at the cutoff frequency fc which gives:

$$Ilf + G \cdot offset , \qquad ( 7 )$$

By multiplying Ilf by two with a multiplication operation 8, the result is 2 (4) which is added to (5)-(7) and the result is:

$$2 \cdot Ilf + ( Ihf + G \cdot offset ) - ( Ilf + G \cdot offset ) = Ilf + Ihf \qquad ( 8 )$$

in the addition/subtraction operation 11.

Because of this calculation process, the stabilization time is no longer linked to a long time-constant integrator but only to the time constant of the low pass filter with frequency fc, which allows much faster calculations. The digital implementation of this device provides the maximum precision for the gain calculations and the low-pass filters which may be duplicated without any error, which is not the case if it had been done in analog knowing that it is difficult to place exactly the same components between the different functions.

Also, it is possible to cascade several devices of this type as shown in FIG. 4 either by cascading digital signal processors 20a, 20b, 20c, . . . 20n the first of which receives a low-frequency signal ILF and the first high-frequency signal IHF1 and comprises a cutoff frequency fc1 and a gain G1, the second receives the output Ilf+Ihf from the first and a signal IHF2 and comprises a cutoff frequency fc1 and a gain equal to or different from the gain G1, and so on for the following signals IHF3, . . . IHFn, or by regrouping them in a single digital signal processor provided with a number of inputs with sufficient analog-to-digital converters in order to extend the bandpass of the measured current.

The device from the present disclosure serves for example to combine signals coming from a low-frequency current probe, for example a Neel effect current probe, and the signals coming from a high-frequency current probe like a Rogowski coil type current probe.

It is possible to implement such a digital measurement device with a microcontroller provided with calculation means performing the calculations corresponding to the digital filters, multiplications and additions or subtractions or else in the form of digital functions integrated in an FPGA component (Field Programmable Gate Array) or in a DSP type component (Digital Signal Processor).

The digitized current data may be processed in a processor 30, which may be an electric network monitoring processor connected to a monitoring device which may comprise display means for displaying the network voltage/current data and/or communication means for communicating the data to a monitoring system.

The present disclosure applies in particular to the protection of direct-current networks generated from rectified aircraft alternating current generators with 400 Hz-800 Hz frequency, in particular high-voltage high current traction networks with protection on HF peaks. The present disclosure also relates to an aircraft equipped with a measurement device such as defined above.

1. A process for current measurement, comprising a digital recombination of a low frequency current signal ILF coming from a low frequency current sensor and at least one high-frequency current signal IHF coming from a high-frequency sensor measured on a single electrical line, where a parasitic continuous offset is added to said high-frequency current, the process comprising the steps of:
a. digitally amplifying said high-frequency signal with an amplifier having gain G which produces an amplified high-frequency signal: G·IHF+G·offset;
b. first filtering of said high-frequency signal by means of a digital low-pass filter with a cutoff frequency fc to get a filtered amplified high-frequency signal Ihf+G·offset:
c. second filtering of said low-frequency current signal ILF with a digital low-pass filter provided with said cutoff frequency fc in order to get a filtered low-frequency signal: Ilf;
d. first summing of the filtered amplified high-frequency signal Ihf+G·offset with the filtered low-frequency current Ilf and filtering of the sum of said signals at frequency fc resulting in a signal: Ilf+Ihf+G·offset;
e. third filtering of said signal Ilf+Ihf+G·offset resulting in a signal Ilf+G·offset from which the Ihf component is deleted;
f. multiplying the signal Ilf by two resulting in a signal: 2 Ilf; and
g. adding/subtracting signals: 2 Ilf+(Ihf+G·offset)−(Ilf+G·offset).

2. The process for current measurement according to claim 1, wherein said steps are preceded by a step of analog-to-digital conversion of said low-frequency current and a step of analog-to-digital conversion of said high-frequency current, where said conversion steps are done on a digitized low-frequency signal and a digitized high-frequency signal.

3. The process for current measurement according to claim 1, wherein the cutoff frequency fc is the cutoff frequency of the signal Ilf.

4. A device for current measurement, comprising calculation means configured for implementing the process according to claim 1.

5. The device for current measurement according to claim 4, wherein said calculation means comprise means for analog-to-digital conversion of the signals.

6. The device for current measurement according to claim 5, further comprising a processor configured to process the data digitized from measured currents.

7. An aircraft comprising the device for current measurement according to claim 4.

8. An aircraft comprising the device for current measurement according to claim 5.

9. An aircraft comprising the device for current measurement according to claim 6.
